(19) United States
(12) Patent Application Publication
(10) Pub. No.: US 2005/0258033 A1
(43) Pub. Date: Nov. 24, 2005

(54) Sputtering target

(76) Inventors: Sho Kumagai, Tokyo (JP); Fumio Odaka, Saitama (JP); Shigeki Endo, Saitama (JP)

Correspondence Address: SUGHRUE MION, PLLC, 2100 PENNSYLVANIA AVENUE, N.W., SUITE 800, WASHINGTON, DC, 20037, US

(21) Appl. No.: 10/522,382

(22) PCT Filed: Jul. 17, 2003
(86) PCT No.: PCT/JP03/09096

§ 371 Date: Jan. 26, 2005

(30) Foreign Application Priority Data
Jul. 30, 2002 (JP) 2002-221652
Jun. 16, 2003 (JP) 2003-170984

(51) Int. Cl. C23C 14/34

(52) U.S. Cl. 204/298.13; 204/298.12

(57) ABSTRACT

A sputtering target which is prepared from a material containing silicon carbide and silicon wherein a volume ratio of silicon carbide ranges from 50% to 70%, when it is defined in such that a volume ratio (%) of silicon carbide=the whole volume of silicon carbide/(the whole volume of silicon carbide+the whole volume of silicon)×100.

### TECHNICAL FIELD

The present invention relates to a sputtering target, and more particularly to a sputtering target in which refractive index in a covering layer of a base material is made adjustable in a wide range.

### BACKGROUND OF THE INVENTION

A sputtering target made of high-purity silicon carbide is known. In such a sputtering target, however, there was a limitation such that a refractive index thereof can be adjusted only within a range of from 1.4 to 3.5 at 633 nm wavelength, even if either a flow rate of oxygen gas and nitrogen gas to be introduced into a sputtering device is controlled, or an electric power to be charged is controlled (for example, see patent document 1: Japanese Patent Application Laid-Open No. 11-61394).

On one hand, although a sputtering target made of high-purity silicon is known, since such sputtering target has 10⁴ Ω·cm or higher in electric resistance, there was an economical disadvantage in that sputtering can be made only in the case where a high-frequency power source (AC) device is used.

Under the circumstances, there is a need of a sputtering target wherein refractive index of a covering layer of which is adjustable in a wide rage by either controlling a flow rate of oxygen gas or nitrogen gas, or by controlling an electric power to be charged. Furthermore, there is a need of sputtering target having 10⁻¹ Ω·cm to 10⁻² Ω·cm in electric resistance by which sputtering becomes possible with the use of a DC power source device.

### DISCLOSURE OF THE INVENTION

As a result of eager study by the present inventors, it was found that the above-described problems could be solved by manufacturing a sputtering target from a material containing silicon carbide and silicon.

That is, the present invention relates to matters described hereinafter.
<1>A sputtering target which is prepared from a material containing silicon carbide and silicon
   wherein a volume ratio of the silicon carbide ranges from about 50% to about 70% when a volume ratio of silicon carbide equals the entire volume of silicon carbide/(the entire volume of silicon carbide+the entire volume of silicon)×100.
<2>The sputtering target as described in the paragraph <1>wherein the volume ratio of silicon carbide ranges from about 55% to about 65%.
<3>The sputtering target as described in the paragraph <1>or <2>wherein the material containing silicon carbide and silicon is prepared by a reaction sintering method.
<4>The sputtering target as described in any one of the paragraphs <1>to <3>wherein a weight ratio of impurities contained in the silicon is about 0.01% or less.
   A Preferred Embodiment FOR CARRYING OUT THE INVENTION

In the following, the present invention will be described in more detail.

First, components used for manufacturing a sputtering target according to the present invention will be described.

(Silicon Carbide Powder)

An example of silicon carbide powder used in the present invention includes α-type, β-type, amorphous silicon carbide powders or mixtures thereof. Furthermore, it is preferred to use a high-purity silicon carbide powder as a raw material silicon carbide powder to obtain a high-purity silicon carbide sintered material.

A grade of β-type silicon carbide powder is not specifically limited, but, for example, a commercially available β-type silicon carbide powder may be used.

As a silicon carbide powder, a mixture of a silicon carbide powder having the most frequent grains of 1.7 to 2.7 μm and a silicon carbide powder of the most frequent grains of 10.5 to 21.5 μm may be used.

A high-purity silicon carbide powder may be obtained by, for example, a process having dissolving a silicon source containing at least one silicon compound, a carbon source containing at least one organic compound producing carbon by a heat treatment, and a polymerization or a crosslinking catalyst in a solvent, and sintering a powder obtained after drying the resulting reaction product under a non-oxidizing atmosphere.

Although a liquid material and a solid material may be used at the same time as the above-described silicon source containing a silicon compound (hereinafter, referred to as simply “silicon source”), at least one member is to be selected from liquid materials. Examples of the liquid material include alkoxysilane (mono-, di-, tri-, and tetra-) and tetraalkoxysilane polymers. Among the alkoxysilanes, tetraalkoxysilanes are preferably used. A specific example includes methoxysilane, ethoxysilane, propoxysilane, butoxysilane and the like. In view of handling, ethoxysilane is preferred. Furthermore, examples of tetraalkoxysilane polymers include low-molecular weight polymers (oligomers) of around 2 to 15 polymerization degree, and silicic acid polymers having a higher polymerization degree in a liquid form. An example of a solid material, which may be used together with the above-described liquid materials, includes silicon oxides. The silicon oxide to be used in the above-described reaction sintering method includes silica gel (a liquid material containing colloidal ultrafine silica, wherein OH group or alkoxyl groups is involved), silicon dioxide (silica gel, fine silica, andquartz powder) and the like in addition to SiO. These silicon sources may be used alone or together with two or more of them.

Among these silicon sources, preferable is a mixture consisting of a tetraethoxysilane oligomer, mixture of a tetraethoxysilane oligomer, and an impalpable powder, or the like in view of good homogeneity and good handling. Moreover, high-purity materials are used for these silicon sources. It is preferred that an initial impurity content of a silicon source is 20 ppm or less, and more preferable is 5 ppm or less.

As the above-described carbon sources containing organic compounds producing carbon by a heat treatment (hereinafter referred optionally to as “carbon source”), a liquid material may be used together with a solid material other than liquid materials alone. Preferable are organic compounds, which exhibit high ratio of residual carbon, and are polymerized or crosslinked by means of a catalyst or a heat treatment. A specific example of them includes a monomer or a prepolymer of resins such as phenolic resin, furan resin, polyimide, polyurethane, and polyvinyl alcohol. In addition, there are liquid materials such as cellulose, sucrose, pitch, and tar. Particularly preferable is resol type phenolic resin. These carbon sources may be used alone or in a mixture of two or more of them. A purity of such carbon sources may be suitably controlled according its rough standard. In this case, when a particularly high-purity silicon carbide powder is required, it is desirable to use an organic compound without containing any metal of 5 ppm or higher content.

A polymerization or crosslinking catalyst used for manufacturing a high-purity silicon carbide powder may be optionally selected in response to a carbon source to be used. In the case when a carbon source is phenolic resin or furan resin, examples therefor include acids such as toluenesulfonic acid, toluene carboxylic acid, acetic acid, oxalic acid, and sulfuric acid. Among others, toluenesulfonic acid is preferably used.

A ratio of carbon and silicon (hereinafter referred simply to as “C/Si ratio”) in a step for manufacturing a high-purity silicon carbide powder being a raw material powder used in the above-described reaction sintering method is defined through elementary analysis of a carbide intermediate obtained by carbonizing a mixture at 1000° C. When a C/Si ratio is 3.0, a free carbon in the resulting silicon carbide should be stoichiometrically 0%. In reality, however, free carbon appears in a low C/Si ratio due to volatilization of SiO gas produced at the same time. It is important to decide previously a proportion of C/Si ratio in such that an amount of free carbon in the resulting silicon carbide powder becomes a proper amount for manufacturing a sintered material and the like. Usually, when a C/Si ratio is selected to be 2.0 to 2.5, free carbon can be suppressed in a sintering step at 1600° C. or a higher temperature in the vicinity of 1 atmospheric pressure, so that such range can be preferably used. When a C/Si ratio is selected to be 2.55 or higher, free carbon increases remarkably. However, since such free carbon exhibits an advantage for suppressing grain growth, production of free carbon may optionally be selected in response to a purpose for forming grains. It is, however, to be noted that when a pressure in the atmosphere is made to be a low pressure or a high pressure, a C/Si ratio for obtaining pure silicon carbide varies. Hence, a C/Si ratio in this case is not necessarily limited to a range of the above-described C/Si ratio.

In the above-described reaction sintering method, it may also be carried out to cure a mixture of a silicon source and a carbon source containing an organic compound which produces carbon by a heat treatment, and then to prepare a powder from the resulting cured mixture in a process for dissolving the mixture of the silicon source and the carbon source into a solvent, and drying the resulting slurry to obtain a powder according to necessity. An example of such hardening method includes a method for crosslinking a mixture by heating, a method for curing a mixture by means of a curing catalyst, and a method for curing a mixture by means of using electron ray or radiant ray. Although a curing catalyst may optionally be selected dependent on a carbon source, acids such as toluenesulfonic acid, toluenecarboxylic acid, acetic acid, oxalic acid, hydrochloric acid, and sulfuric acid; or amines such as hexamine may be used in case of applying phenolic resin or furan resin. Catalysts selected from them are dissolved or dispersed into a solvent to admix the catalysts. An example of such solvent includes lower alcohols (for example, ethyl alcohol or the like), ethyl ether, acetone or the like.

A silicon source and a carbon source containing an organic compound producing carbon by a heat treatment are dissolved into a solvent, and a powder obtained by drying the resulting solution is heated for carbonization. The carbonization is conducted by heating the powder in a non-oxidizing atmosphere of nitrogen, argon or the like at 800° C. to 1000° C. for 30 to 120 minutes.

Furthermore, the resulting carbides are heated in a non-oxidizing atmosphere of argon or the like at 1350° C. to 2000° C., to produce silicon carbide. A sintering temperature and a period of time for sintering materials may suitably be selected in response to properties such as a desired particle diameter of the resulting product. In this respect, sintering materials at a temperature of 1600° C. to 1900° C. is preferred for more effective production of carbides.

When it is required to obtain higher-purity of silicon carbide powder, impurities can be more efficiently removed by a heat treatment at 2000° C. to 2100° C. for 5 to 20 minutes in case of the above-mentioned sintering step.

From these results, as a manner for obtaining a silicon carbide powder particularly having much higher-purity, a method for manufacturing a raw material powder described in a method for manufacturing a single crystal of Japanese Patent Application Laid-Open No. 9-48605 filed previously by the present applicant may be utilized. That is, the above-described application relates to a method for manufacturing a high-purity silicon carbide powder characterized by including a silicon carbide production step for obtaining a silicon carbide powder by sintering a mixture obtained from a silicon source of at least one member selected from a high-purity tetraalkoxysilane and a tetraalkoxysilane polymer, and a carbon source of a high-purity organic compound producing carbon by a heat treatment through heating under a non-oxidizing atmosphere, these silicon and carbon sources being homogeneously admixed with each other; and a post-treating step for maintaining the resulting silicon carbide powder at a temperature ranging from 1700° C. or higher to less than 2000° C., and implementing at least one heat treatment at a temperature of 2000° C. to 2100° C. for 5 to 20 minutes during maintaining the former temperature range; whereby a silicon carbide powder containing impurity elements each content of which is less than 0.5 ppm is obtained. Since the resulting silicon carbide powder exhibits nonuniform sizes, it is processed through pulverization and classification so as to conform to the above-described particle size.

In the case when nitrogen is introduced in a step for manufacturing a silicon carbide powder, first, a silicon source, organic materials consisting of a carbon source and a nitrogen source, and a polymerization or a crosslinking catalyst are homogeneously mixed with each other. As mentioned above, when organic materials consisting of a carbon source of phenolic resin or the like and a nitrogen source of hexamethylenetetramine or the like, and a polymerization or a crosslinking catalyst of toluenesulfonic acid or the like are dissolved in a solvent such as ethanol, it is preferable to sufficiently admix the resulting solution with a silicon source of an oligomer of tetraethoxysilane.

(Carbon Source)

Materials used for the carbon source are high-purity organic compounds producing carbon by a heat treatment. In this connection, the organic compounds applied as the carbon source may be used alone, or two or more of them may be used together. It is preferred that electroconductivity is given to an organic compound for producing carbon by a heat treatment. A specific example of such organic compounds includes phenolic resin, furan resin epoxy resin, and phenoxy resin each having a high residual carbon ratio; and a variety of saccharides such as monosaccharides, e.g. glucose and the like, oligosaccharides, e.g. sucrose and the like, and polysaccharides, e.g. cellulose, starch and the like. For the sake of admixing homogeneously with a silicon carbide powder, these organic compounds of a material in the form of liquid at normal temperature, a material, which is dissolved in a solvent, and a thermoplastic or a hot-melt material, which is molten or liquefied by heating it are principally used. Among these, phenolic resin from which a molded article having a high strength is obtained, and particularly resol type phenolic resin is preferably used.

(Silicon Source)

A silicon source is a member selected from at least one of high-purity tetraalkoxysilanes, the polymers thereof, and silicon oxide. In the present invention, a term “silicon oxide” includes silicon dioxide, and silicon monoxide. A specific example of silicon sources includes alkoxysilanes represented by tetraethoxysilane, the oligomers thereof, silicic acid polymers having higher polymerization degrees, and silicon oxide compounds such as silica sol, and pulverized silica. An example of alkoxysilanes includes methoxysilane, ethoxysilane, propoxysilane, butoxy silane and the like. Among these, ethoxysilane is preferably used in view of a handling property.

The term “oligomer” used herein means a polymer having around 2 to 15 polymerization degrees. Among oligomers for these silicon sources, oligomers of tetraethoxysilane, and mixtures of the oligomers of tetraethoxysilane and pulverized silica, and the like are preferred from the viewpoints of good homogeneity and good handling property. In addition, silicon sources for such oligomers should be prepared from high-purity materials wherein an initial content of impurities contained in the materials is preferably 20 ppm or less, and more preferable is 5 ppm or less. Furthermore, it is preferred that a weight ratio of impurities contained in the above-described silicon is 0.01% or less.

(Volume Ratio of Silicon Carbide)

A sputtering target according to the present invention contains 50 to 70% of silicon carbide, and preferably 55 to 65% thereof in the case where a volume ratio (%) of silicon carbide=the whole volume of silicon carbide/(the whole volume of silicon carbide+the whole volume of silicon)×100.

For achieving the above-described volume ratio of silicon carbide, there is a method for admixing at least two types of silicon carbide powders having different particle diameters with each other at a predetermined ratio in a slurry preparing step. More specifically, when admixing is conducted at a volume ratio of a silicon carbide powder having 2.3 μm diameter/a silicon carbide powder having 16.4 μm diameter=50/50, a silicon carbide sintered material having 50% volume ratio can be obtained. Furthermore, when admixing is conducted at a volume ratio of a silicon carbide powder having 2.3 μm diameter/a silicon carbide powder having 16.4 μm diameter=70/30, a silicon carbide sintered material having 70% volume ratio can be obtained.

According to such construction of the invention, a sputtering target having a low volume resistivity wherein a refractive index of a covering layer may be selected within a wide range can be obtained.

(Method for Manufacturing Sputtering Target)

In the following, a preferred embodiment of a method for manufacturing a sputtering target to which is applied a reaction sintering method will be described.

One preferred embodiment of the method for manufacturing a sputtering target includes (1) dissolving or dispersing a silicon carbide powder and a carbon source into a solvent to manufacture a mixed powder in a slurry form, (2) pouring the resulting mixed powder into a mold and drying the same to obtain a green material, (3) calcinating the resulting green material at 1200 to 1800° C. under a vacuum or inert gas atmosphere to obtain a calcined material, and (4) impregnating the resulting calcined material with molten metallic silicon due to capillary phenomenon to react free carbon in the above-described calcined material with the silicon aspirated into the above-described calcined material due to capillary phenomenon thereby to obtain a silicon carbide material. In the following, the above-described method for manufacturing a sputtering target will be described in detail in each step.

(1) Manufacturing a Mixed Powder in a Slurry Form

A slurry-form mixed powder is manufactured by dissolving or dispersing a silicon carbide powder and a carbon source, in addition, an organic binder or a defoamer, if desired, into a solvent. When materials to be dissolved or dispersed are sufficiently agitated and admixed at the time of dissolving or dispersing these materials, pores can be uniformly dispersed into a green material.

In this case, a silicon carbide sintered material having 50% volume ratio of silicon carbide is obtained through mixing of a silicon carbide powder having 2.3 μm diameter/a silicon carbide powder having 16.4 μm diameter (volume ratio)=50/50. Furthermore, a silicon carbide sintered material having 70% volume ratio of silicon carbide is obtained through mixing of a silicon carbide powder having 2.3 μm diameter/a silicon carbide powder having 16.4 μm diameter (volume ratio)=70/30.

An example of the above-described solvent includes water, lower alcohols such as ethyl alcohol, ethyl ether, acetone and the like. It is preferable to use a solvent having a low content of impurities.

Moreover, an organic binder may be added to the materials to be mixed in the case when a slurry-form admixed powder is manufactured from a silicon carbide powder. An example of such organic binder includes a deflocculating agent, a powder-binding agent and the like. In this case, a nitrogen-base compound is preferred as a deflocculating agent for elevating further an advantageous effect of affording electroconductivity to the resulting admixed powder. For example, ammonia, polyacrylic acid ammonium salt and the like are suitably used. As a powder-binding agent, polyvinyl alcohol urethane resin (e.g. water-soluble polyurethane) and the like are suitably used.

Besides, a defoamer may be added to materials to be admixed. An example of such defoamer includes a silicon defoamer and the like.

The above-described agitation and admixing may be carried out by a well-known agitation and admixing means, for example, a mixer, a planetary ball mill and the like. Such agitation and admixing is conducted for 6 to 48 hours, particularly it is preferred to agitate and admix materials for 12 to 24 hours.

(2) Preparing a Green Material

To pour a slurry-form mixed powder into a mold to obtain a molded article, cast molding is suitably utilized in usual. The slurry-form mixed powder is poured into a mold at the time of cast molding, it is allowed to stand, and the resulting molded powder is removed from the mold, thereafter, the molded powder is dried by heating or air-dried under a temperature condition of 40 to 60° C. to remove a solvent, whereby a green material having a specified dimension can be obtained.

In the present invention, the term “green material” means a silicon carbide molded article prior to reaction sintering which contains a number of pores inside the molded article and is prepared from a slurry-form mixed powder by removing a solvent contained therein.

(3) Obtaining a Calcined Material

To obtain a sputtering target having a high bending strength, it is preferred to calcinate a green material prior to a sintering step. By applying such calcinating step, a very small amount of water and organic components such as a deflocculation agent, and a binder can be completely removed.

A calcination temperature ranges from 1200 to 1800° C., and preferably ranges from 1500 to 1800° C. When it is less than 1200° C., contacting states among silicon carbide powders cannot be sufficiently promoted, so that contact strength become insufficient, resulting in inconvenience in handling of the silicon carbide powder. On the other hand, when it exceeds 1800° C., grain growth of a silicon carbide powders in a green material becomes remarkable, so that the following permeation of molten high-purity silicon becomes insufficient.

A rate of temperature rising for the above-described calcination is preferably to be 1 to 3° C./min. until a temperature reaches 800° C., and it is preferred to be 5 to 8° C./min. during a temperature elevating from 800° C. to the maximum temperature. In this connection, it may be suitably determined with taking a shape, a dimension and the like of a green material to be manufactured into consideration.

A time for maintaining the above-described maximum temperature for calcination ranges preferably from 10 to 120 minutes, and more preferably ranges from 20 to 60 minutes. In this case, it may be suitably determined with taking a shape, a dimension and the like of a green material to be manufactured into consideration.

The above-described calcination is desirably carried out under a vacuum or an inert gas atmosphere from the viewpoint of preventing oxidation.

As a result of such calcination, a sintered material having 300 MPa or higher bending strength at room temperature can be obtained. Moreover, it becomes possible to obtain a sintered material without accompanying any defect such as cracks, crazing or the like even in a complicated contour of the sintered material.

In the present invention, the term “calcined material” means a silicon carbide molded article prior to reaction sintering which is obtained by calcinating the above-described green material and by which pores and impurities have been removed therefrom.

(4) Obtaining a Silicon Carbide Sintered Material

A calcined material manufactured through the above-described steps is immersed in high-purity metallic silicon molten by heating it at a temperature equal to or higher than a melting point thereof, specifically a temperature ranging from 1450 to 1700° C. under a vacuum or an inert gas atmosphere. When the calcined material is immersed into the molten metallic silicon, the liquefied silicon permeates into pores in the calcined material due to capillary phenomenon, and hence, the silicon reacts with free carbon in the calcined material. As a result of the reaction, silicon carbide is produced, and the pores in the calcined material are filled with the silicon carbide thus produced.

Since the reaction of silicon with free carbon appears at a temperature of around 1420 to 2000° C. as described in the step for manufacturing a silicon carbide powder, the reaction of such silicon with free carbon proceeds at the stage wherein the molten high-purity metallic silicon heated up to between 1450 and 1700° C. permeates into the sintered material.

On one hand, a period of time for immersing a calcined material in molten metallic silicon is not specifically limited, but it may be suitably determined depending on the size of such calcined material and the amount of free carbon contained in the calcined material. High-purity metallic silicon is heated up to between 1450 and 1700° C., and preferably between 1550 and 1650° C. for melting the same. In this case, when such temperature for melting the high-purity metallic silicon is lower than 1450° C., a viscosity of the high-purity metallic silicon increases, so that it does not permeate into the calcined material due to capillary phenomenon, while when such temperature exceeds 1700° C., volatilization becomes remarkable, resulting in damages in a furnace casing and the like.

An example of high-purity metallic silicon includes powdered, granular, and aggregated metallic silicon and the like. Two to five mm aggregated metallic silicon is preferably used. In the present invention, the term “high purity” means a content of impurities being less than 1 ppm.

As described above, a high-density sputtering target having good electrical properties can be obtained by allowing free carbon contained in a calcined material to react with silicon, whereby pores in the calcined material is filled with the silicon carbide thus produced.

In the above-described reaction sintering method, there is no limitation as to particularly manufacturing equipment and the like so far as the above-described heating condition in the present invention is satisfied, and hence, well-known heating furnaces and reactors may be used.

A total content of impurities in a sputtering target obtained by the present invention is less than 5 ppm, preferably less than 3 ppm, and more preferably less than 1 ppm. However, a content of impurities by chemical analysis exhibits only a meaning as a reference value from the viewpoint of applicability for a field of semiconductor industry. Practically, evaluations become different from a condition wherein impurities are distributed uniformly, or distributed locally and unevenly.

(Manner for Application)

When a sputtering operation is made upon a base material with the use of a sputtering target of the present invention in accordance with a conventional well-known sputtering method, a silicon carbide covering layer may be provided on the base material.

Optical characteristics such as light transmittance, refractive index, optical reflectance and the like of a silicon carbide covering layer to be manufactured in accordance with a sputtering method may be controlled by an electric power to be charged at the time of sputtering, a flow rate of oxygen gas or nitrogen gas to be introduced (to be zero in the flow rate of gas (no introduction of gas) may be applicable), and a sputtering period of time (i.e. a thickness of a silicon carbide covering layer to be formed).

Since a sputtering target according to the present invention exhibits electroconductivity as mentioned later, sputtering can be made with the use of a DC power device, in other words, by the application of DC sputtering, or DC magnetron sputtering.

As a basic condition for film formation, it is preferred that an ultimate vacuum pressure is 3×10⁻⁴ Pa or less (more specifically, 4×10⁻⁵ Pa to 3×10⁻⁴ Pa). Furthermore, it is preferred that a vacuum pressure at the time of film formation is 6.7×10⁻¹ Pa (5 mtorr) or less in the case where a flow rate of Ar gas to be introduced is 10 ccm. In addition, it is preferred that a temperature of a base material is room temperature.

As a base material, inorganic materials such as glass, and ceramics; metallic materials; and organic materials such as PMMA, and PET may be applied.

### EXAMPLES

In the following, although the present invention will be specifically described with reference to examples and comparative examples, the invention is not limited to the following examples as a matter of course.

<Preparation of Sputtering Target>

### Examples 1 to 3

### Preparation of PB-R

A sputtering target of a composite material made of silicon carbide wherein a volume ratio of the silicon carbide is 70%, and silicon (hereinafter referred optionally to as “PB-R”) was prepared through admixing of a silicon carbide powder having 2.3 μm diameter/a silicon carbide powder having 16.4 μm diameter (volume ratio)=50/50 in a slurry preparing step in accordance with the reaction sintering method described in the above column of preferred embodiment of the invention.

It is to be noted that a particle diameter of silicon carbide powder is selected to be the most frequent diameter when classified by a classifier.

In the case when a sputtering operation was effected, a sputtering target was molded into a dimension of 100 mm diameter×5 mm thickness and then it was used.

### Comparative Examples 1 to 3

### Preparation of PB-S

A sputtering target made of silicon carbide was prepared in accordance with a hot press method disclosed in Example 1 of filling application (Japanese Patent Application Laid-Open No. 10-67565) filed previously by the present applicants (hereinafter referred optionally to as “PB-S”). That is, 1410 g of a high-purity silicon carbide powder (1.1 μm average particle diameter: a silicon carbide powder having 5 ppm or less impurity content which was manufactured according to a manufacturing method of Japanese Patent Application No. 7-241856: containing 1.5% by weight of silica) and a solution prepared by dissolving 90 g of high-purity liquid resol type phenolic resin having a moisture content of 20% (a residual carbon ratio being 50% after thermal decomposition) into 2000 g of ethanol were agitated with a planetary ball mill for 18 hours to admix them sufficiently. Thereafter, the resulting admixture was warmed up to between 50 and 60° C., whereby ethanol was subjected to evaporation to dryness, and the resulting product was screened with a 500 μm mesh to obtain a homogeneous silicon carbide raw material powder. A metal mold was filled with 1000 g of the raw material powder and pressed at 130° C. for 20 minutes thereby to obtain a molded article.

The molded article was placed in a mold made of graphite, and was hot-pressed in the following condition. As a hot pressing apparatus, a high-frequency induction heating type 100 t hot press was used. (Condition of sintering step) Under a vacuum condition of 10⁻⁵ to 10⁻⁴ torr, temperature was raised from room temperature to 700° C. gradually for taking 6 hours, and the resulting temperature was maintained for 5 hours.

Under a vacuum condition, a temperature was raised from 700° C. to 1200° C. for taking 3 hours, thereafter, a temperature was raised from 1200° C. to 1500° C. for taking 3 hours, and the resulting temperature was maintained for 1 hour. Furthermore, a pressure of 500 kgf/cm² was applied, a temperature was raised from 1500° C. to 2200° C. for taking 3 hours under argon atmosphere, and the resulting temperature was maintained for 1 hour.

In the case when a sputtering operation is effected, a sputtering target molded into a dimension of 100 mm diameter×5 mm thickness was used.

<Sputtering Method>

A sputtering operation was made in the following condition.

Sputtering equipment: a planar magnetron sputter apparatus (manufactured by Nippon Vacuum Technology Co., Ltd.), Electric power source: DC, Base material: Glass plate, Distance between the target material and the base material: 70 mm, Ultimate vacuum pressure in the sputtering apparatus: 3×10⁻⁴ Pa or less, Base plate temperature: room temperature, Refractive index measurement (real part is represented by n, imaginary part is represented by k): Ellipsometry (manufactured by Nippon Bunkoh)

### Example 1/Comparative Example 1

To observe a relationship between an amount of electric power to be charged and a refractive index, sputtering operations were made while maintaining an amount of gas to be supplied at a constant value as shown in Table 1 and changing the amount of electric power to be charged in 1000 (W), 500 (W), and 100 (W).

TABLE 1

| | | Amount of gas to be | | | Amount of electric |
|---|---|---|---|---|---|
| | | suppied (CCM) | | | power to be charged |
| | Target Board | Ar | N2 | O2 | (W) |
| Example 1 | PB-R | 10 | 0 | 0 | 1000, 500, 100, |
| Comparative | PB-S | 10 | 0 | 0 | 1000, 500, 100, |
| Example 1 | | | | | |

### Examples 2, 3/Comparative Examples 2, 3

To observe a relationship between the amounts of gases (N₂, O₂) to be supplied and the refractive index, sputtering operations were made while changing the amounts of N₂ or O₂ and while maintaining an amount of Ar gas to be supplied and an amount of electric power to be charged at constant values, respectively.

TABLE 2

| | | | Amount of | Amount of gas to | | |
|---|---|---|---|---|---|---|
| | | | electric | be supplied (CCM) | | |
| | | Target Board | power to be | Ar | N₂ | O₂ |
| Example | 2 | PB-R | 500 | 10 | 0˜6 | 0 |
| | 3 | PB-R | 500 | 10 | 0 | 0˜6 |
| Comparative | 2 | PB-S | 500 | 10 | 0˜6 | 0 |
| Example | 3 | PB-S | 500 | 10 | 0 | 0˜6 |

Refractive indexes of covering layers formed on glass plates at the measured optical wavelength of 633 nm in the above-described examples 1 to 3 and the above-described comparative examples 1 to 3 are collectively shown in Table 3 wherein n represents real parts and k represents imaginary parts in the column of refractive index.

TABLE 3

| | | Amount of | Amount of | | | | |
|---|---|---|---|---|---|---|---|
| | | electric power | gas to be | | | Reflective | |
| | Target | to be charged | supplied (CCM) | | | Index | |
| | Board | (W) | Ar₂ | N₂ | O₂ | n | k |
| Example | | | | | | | |
| 1 | PB-R | 500 | 10 | 0 | 0 | 4.14 | 0.50 |
| | | | 10 | 1 | 0 | 3.07 | 0.15 |
| | | | 10 | 2 | 0 | 2.62 | 0.06 |
| | | | 10 | 3 | 0 | 2.37 | 0.04 |
| | | | 10 | 4 | 0 | 2.26 | 0.04 |
| | | | 10 | 5 | 0 | 2.18 | 0.04 |
| | | | 10 | 6 | 0 | 2.13 | 0.03 |
| 2 | PB-R | 500 | 10 | 0 | 0 | 4.14 | 0.50 |
| | | | 10 | 0 | 1 | 3.52 | 0.29 |
| | | | 10 | 0 | 2 | 2.51 | 0.07 |
| | | | 10 | 0 | 3 | 1.60 | 0.02 |
| | | | 10 | 0 | 4 | 1.40 | 0.01 |
| | | | 10 | 0 | 5 | 1.40 | 0.00 |
| | | | 10 | 0 | 6 | 1.41 | 0.00 |
| 3 | PB-R | 1000 | 10 | 0 | 0 | 4.16 | 0.50 |
| | | 500 | 10 | 0 | 0 | 4.14 | 0.50 |
| | | 100 | 10 | 0 | 0 | 4.04 | 0.46 |
| Comparative | | | | | | | |
| Example | | | | | | | |
| 1 | PB-S | 500 | 10 | 0 | 0 | 3.35 | 0.25 |
| | | | 10 | 1 | 0 | 2.76 | 0.11 |
| | | | 10 | 2 | 0 | 2.53 | 0.09 |
| | | | 10 | 3 | 0 | 2.38 | 0.09 |
| | | | 10 | 4 | 0 | 2.30 | 0.09 |
| | | | 10 | 5 | 0 | 2.24 | 0.09 |
| | | | 10 | 6 | 0 | 2.21 | 0.08 |
| 2 | PB-S | 500 | 10 | 0 | 0 | 3.35 | 0.25 |
| | | | 10 | 0 | 1 | 2.82 | 0.13 |
| | | | 10 | 0 | 2 | 2.03 | 0.06 |
| | | | 10 | 0 | 3 | 1.63 | 0.04 |
| | | | 10 | 0 | 4 | 1.45 | 0.01 |
| | | | 10 | 0 | 5 | 1.42 | 0.00 |
| | | | 10 | 0 | 6 | 1.40 | 0.00 |
| 3 | PB-S | 1000 | 10 | 0 | 0 | 3.36 | 0.24 |
| | | 500 | 10 | 0 | 0 | 3.35 | 0.25 |
| | | 100 | 10 | 0 | 0 | 3.33 | 0.26 |

Remarks
Measured optical wavelength: 633 nm

To examine a volume resistivity of a sputtered film, a sputtering operation was made upon a sputtering target prepared as described above under the conditions shown in Table 4. Then, a volume resistivity of a covering layer formed on a glass plate was examined. The experimental conditions and the experimental results are collectively shown Table 4.

TABLE 4

| | Flow rate | Flow rate | Amount of | Applied | |
|---|---|---|---|---|---|
| | of Ar | of active | electric | voltage at | |
| | gas | gas | power to | the time of | Volume |
| Target | introduced | introduced | be charged | measurement | resistivity |
| Board | (ccm) | (ccm) | (W) | (V) | (Ω · cm) |
| PB-R | 10 | 0 | 100 | 10 | 1.7 × 10² |
| PB-R | 10 | 0 | 500 | 10 | 1.7 × 10² |
| PB-R | 10 | 0 | 1000 | 10 | 1.7 × 10² |
| PB-R | 10 | N₂:0.5 | 500 | 50 | 3.0 × 10³ |
| PB-R | 10 | O₂:0.5 | 500 | 50 | 6.6 × 10² |
| PB-S | 10 | 0 | 100 | 10 | 3.7 × 10¹ |
| PB-S | 10 | 0 | 500 | 10 | 2.4 × 10¹ |
| PB-S | 10 | 0 | 1000 | 10 | 2.2 × 10¹ |

Remarks
Measuring device: Roresta-GP MCP-T600,ASP probe

From the above experimental results, it was found that when a sputtering target according to the present invention was used, a refractive index of a covering layer could be selected in a wide range. Furthermore, it was found that a sputtering target according to the present invention had a low volume resistivity, so that a sputtering operation could be made by the use of a DC power source device.

It will be acknowledged by those skilled in the art that a preferred embodiment of the present invention corresponds to the description as mentioned above and that various changes and modifications may be made without deviating from the spirit and the scope of the present invention.

The present application claims the Convention priority based on the Japanese patent application No. 2002-221652 (filed Jul. 30, 2002) and Japanese Patent Application No. 2003-170984 (filed Jun. 16, 2003) and the whole contents of these specifications are to be incorporated herein for reference.

### INDUSTRIAL APPLICABILITY

According to the present invention, when either of a flow rate of oxygen gas or nitrogen gas, or an electric power to be charged is controlled, a sputtering target wherein a refractive index of a covering layer thereof is adjustable in a wide range is obtained.

Moreover, according to the present invention, a sputtering target by which a sputtering operation can be made with the use of a DC power source device is obtained.

1. A sputtering target comprising:
a material containing silicon carbide and silicon
wherein a volume ratio of the silicon carbide ranges from about 50% to about 70% when a volume ratio of silicon carbide equals the entire volume of silicon carbide/(the entire volume of silicon carbide+the entire volume of silicon)×100.

2. The sputtering target as claimed in claim 1 wherein the volume ratio of the silicon carbide is about 55% to about 65%.

3. The sputtering target as claimed in claim 1, wherein the material containing silicon carbide and silicon is prepared by a reaction sintering method.

4. The sputtering target as claimed in claim 1, wherein a weight ratio of impurities contained in the silicon is about 0.01% or less.

5. The sputtering target as claimed in claim 1, wherein a volume resistivity of a covering layer formed on a glass plate is about 3.0×10³ (Ω·cm) or less.

6. The sputtering target as claimed in claim 1, wherein the silicon carbide is a powder comprising, a mixture of a silicon carbide powder having a most frequent grains of about 1.7 to about 2.7 μm and a silicon carbide powder having most frequent grains of about 10.5 to about 21.5 μm is used.

7. A method for manufacturing a sputtering target comprising:
dispersing a silicon carbide powder and a carbon source into a solvent to provide a mixed powder in a slurry form,
pouring the resulting mixed powder into a mold and drying the same to obtain a green material,
calcinating the resulting green material at about 1200 to about 1800° C. under a vacuum or inert gas atmosphere to obtain a calcined material, and
impregnating the resulting calcined material with molten metallic silicon by capillary action to react free carbon in the calcined material with the silicon aspirated into the calcined material due to the capillary action phenomenon thereby obtaining a silicon carbide material.

8. The sputtering target as claimed in claim 1, wherein the refractive indexes of covering layers formed on glass plates at the measured optical wavelength of 633 nm are 4.16 or less.
